(19) United States
(12) Patent Application Publication
(10) Pub. No.: US 2025/0129516 A1
(43) Pub. Date: Apr. 24, 2025

(54) SUBSTRATE WITH DIELECTRIC THIN FILM, OPTICAL WAVEGUIDE COMPONENT, AND OPTICAL MODULATION COMPONENT

(71) Applicant: TDK Corporation, Tokyo (JP)

(72) Inventors: Shusaku UMEMOTO, Tokyo (JP); Kenji SASAKI, Tokyo (JP); Takashi KIKUKAWA, Tokyo (JP)

(73) Assignee: TDK Corporation, Tokyo (JP)

(21) Appl. No.: 18/919,683

(22) Filed: Oct. 18, 2024

(30) Foreign Application Priority Data
Oct. 23, 2023 (JP) 2023-181574

(51) Int. Cl. C30B 29/30; G02F 1/035

(52) U.S. Cl. CPC C30B 29/30; G02F 1/035; G02F 2202/20

(57) ABSTRACT

A substrate with a dielectric thin film includes: a single crystal substrate; and a dielectric thin film formed in contact with a main surface of the single crystal substrate, wherein the dielectric thin film has a thickness of 0.5 μm to 2 μm and is made of a lithium niobate film that is an epitaxial film with a c-axis orientation, the dielectric thin film has a twin crystal structure of LiNbO₃ of a first crystal and a second crystal corresponding to a crystal in which the first crystal is rotated 180° around the c-axis, the first crystal and the second crystal in an upper region of the dielectric thin film, excluding a lower region from the single crystal substrate to half of a thickness direction in the dielectric film, have maximum domain widths of 80 nm to 300 nm.

### CROSS-REFERENCES TO RELATED APPLICATIONS

This application relies for priority upon Japanese Patent Application No. 2023-181574 filed on Oct. 23, 2023, the entire content of which is hereby incorporated herein by reference for all purposes as if fully set forth herein.

### BACKGROUND

The present disclosure relates to a substrate with a dielectric thin film, an optical waveguide component and an optical modulation component using the same.

Conventionally, there is an optical modulation component that uses a lithium niobate film epitaxially grown on a substrate.

For example, Patent Document 1 describes an optical modulation component using a substrate with a dielectric thin film. Patent Document 1 describes a substrate with a dielectric thin film, which includes a dielectric thin film made of a c-axis oriented lithium niobate film epitaxially formed on a main surface of a single crystal substrate. Patent Document 1 also describes a dielectric thin film having a twin crystal structure including a first crystal and a second crystal corresponding to a crystal in which the first crystal is rotated 180° around the c-axis, and in a pole figure measurement by an X-ray diffraction method, the ratio of a first diffraction intensity of a first crystal to a second diffraction intensity of a second crystal is 0.5 or more and 2.0 or less.

Furthermore, Patent Document 2 describes an optical modulator having a lithium niobate film which is an epitaxial film formed on the main surface of a single crystal substrate and has a ridge-shaped portion, a buffer layer formed on the ridge-shaped portion, a first electrode formed on the buffer layer, and a second electrode formed in contact with the upper surface and/or a step portion of the lithium niobate film.

Also, Patent Document 3 describes an optical waveguide device that includes an optical waveguide formed in the surface of an electro-optic crystal substrate, first and second electrodes for applying an electric field that changes the refractive index of the optical waveguide, and a buffer layer formed on the substrate between the first and second electrodes. Patent Document 3 describes an optical waveguide device that changes the refractive index by applying an electric field to an optical waveguide formed in the surface of an electro-optical crystal substrate such as lithium niobate (LiNbO₃).

### PRIOR ART REFERENCES

### Patent Documents

Patent Document 1: WO 2018/016428 A1
Patent Document 2: JP 2014-142411 A
Patent Document 3: JP 3001027 B2

### SUMMARY

An optical waveguide component and an optical modulation component using a substrate with a dielectric thin film having a lithium niobate film epitaxially grown on the substrate are more productive than an optical waveguide component and an optical modulation component using a lithium niobate single crystal substrate. This is because a substrate with a dielectric thin film having a lithium niobate film epitaxially grown on the substrate can form a lithium niobate film of a desired thickness by adjusting the film deposition conditions. In other words, when a substrate with a dielectric thin film having a lithium niobate film epitaxially grown on the substrate is used, it is not necessary to adjust the thickness by cutting or polishing the lithium niobate single crystal substrate as in the case of using a lithium niobate single crystal substrate. Moreover, a substrate with a dielectric thin film having a lithium niobate film epitaxially grown on the substrate is less expensive than a lithium niobate single crystal substrate.

However, in the optical waveguide component and the optical modulation component using the lithium niobate film epitaxially grown on the substrate, the thickness of the lithium niobate film may be a design limitation of the optical waveguide component and the optical modulation component. More specifically, the lithium niobate film epitaxially grown on the substrate preferably has a sufficient film thickness so that the optical waveguide component and the optical modulation component applicable to a wide range of light from visible light to infrared light can be obtained. However, the lithium niobate film epitaxially grown on the substrate is prone to cracking, and there is a disadvantage that the thicker the film, the more likely the cracking occurs.

For this reason, there is a demand for a substrate with a dielectric thin film having a lithium niobate film epitaxially grown on a substrate, while the lithium niobate film is less susceptible to cracking.

In addition, in an optical modulation component using a lithium niobate film, the modulated waveform moves depending on the DC (direct current) voltage applied to the electrodes of the optical modulation component. The modulated waveform in an optical modulation component using a lithium niobate film changes with the application time of the DC (direct current) voltage. This change in the modulated waveform over time is called DC drift.

In an optical modulation component using a substrate with a dielectric thin film having a lithium niobate film epitaxially grown on a conventional substrate, the DC drift is larger than that of an optical modulation component using a lithium niobate single crystal substrate, and therefore there has been a demand for reducing the DC drift.

The present disclosure has been made in consideration of the above problems, and aims to provide a substrate with a dielectric thin film that has a lithium niobate film epitaxially grown on the substrate, and that is capable of forming an optical modulation component in which cracks are unlikely to occur in the lithium niobate film and DC drift is suppressed.

Another object of the present disclosure is to provide an optical waveguide component that is provided with a substrate having a dielectric thin film made of a lithium niobate film, and that can form an optical modulation component in which cracks are unlikely to occur in the lithium niobate film and DC drift is suppressed.

Another object of the present disclosure is to provide an optical modulation component including a substrate having a dielectric thin film made of a lithium niobate film, in which cracks are less likely to occur in the lithium niobate film and DC drift is suppressed.

A substrate with a dielectric thin film according to one aspect of the present disclosure includes: a single crystal substrate; and a dielectric thin film formed in contact with a main surface of the single crystal substrate, wherein the dielectric thin film has a thickness of 0.5 μm to 2 μm and is made of a lithium niobate film that is an epitaxial film with a c-axis orientation, the dielectric thin film has a twin crystal structure of LiNbO₃ of a first crystal and a second crystal corresponding to a crystal in which the first crystal is rotated 180° around the c-axis, the first crystal and the second crystal in an upper region of the dielectric thin film, excluding a lower region from the single crystal substrate to half of a thickness direction in the dielectric film, have maximum domain widths of 80 nm to 300 nm, the maximum domain widths of the first crystal and the second crystal are median values of measured values obtained by setting a measurement region having a length of 4 μm in a cross section at an arbitrary location on an interface between the dielectric thin film and the single crystal substrate and measuring crystal domain widths of 10 or more arbitrary first and second crystals present within the measurement region, each of the crystal domain widths being a crystal width in a direction perpendicular to a growth direction of each crystal and maximum dimension within the thickness direction.

The substrate with a dielectric thin film of the present disclosure is made of a lithium niobate film, which is an epitaxial film having a c-axis orientation formed on and in contact with the main surface of a single crystal substrate, and has a dielectric thin film having a twin crystal structure of LiNbO₃ including a first crystal and a second crystal corresponding to a crystal in which the first crystal is rotated 180° around the c-axis. Therefore, in the substrate with a dielectric thin film of the present disclosure, the twin crystal structure of LiNbO₃ relieves distortion and stress caused by the difference in lattice constant and the difference in linear expansion coefficient between the single crystal substrate and the lithium niobate film. Therefore, the substrate with a dielectric thin film of the present disclosure is less susceptible to cracks in the lithium niobate film.

Furthermore, in the substrate with a dielectric thin film of the present disclosure, the dielectric thin film is made of a lithium niobate film, which is an epitaxial film with a c-axis orientation, and is less susceptible to cracking. Therefore, the thickness of the lithium niobate film can be easily adjusted to a thickness suitable for, for example, the production of optical waveguide components and optical modulation components using the substrate with a dielectric thin film.

Therefore, the substrate with the dielectric thin film of the present disclosure can be preferably used when producing an optical waveguide component and an optical modulation component.

The dielectric thin film of the dielectric thin film substrate of the present disclosure has a thickness of 0.5 μm to 2 μm, and the first crystal and the second crystal present within a measurement region having a length of 4 μm in a cross section in an upper region of the dielectric thin film, excluding a lower region from the single crystal substrate to half of a thickness direction in the dielectric film, have maximum domain widths of 80 nm to 300 nm. Therefore, in the optical modulation component using the dielectric thin film substrate, when a DC (direct current) voltage is applied in an in-plane direction from above the dielectric thin film, the number of twin boundaries crossed by the DC (direct current) electric field moving through the twin structure of LiNbO₃ becomes appropriate. As a result, an optical modulation component having a signal electrode and a ground electrode provided on the dielectric thin film of the dielectric thin film substrate of the present disclosure has suppressed DC drift.

The optical waveguide component of the present disclosure includes the substrate with the dielectric thin film of the present disclosure, and therefore the optical waveguide component of the present disclosure is capable of forming an optical modulation component in which cracks are unlikely to occur in the lithium niobate film forming the dielectric thin film, and in which DC drift is suppressed when a DC (direct current) voltage is applied in the in-plane direction from above the dielectric thin film.

Furthermore, since the optical modulation component of the present disclosure includes a substrate with a dielectric thin film of the present disclosure, cracks are less likely to occur in the lithium niobate film forming the dielectric thin film, and DC drift is suppressed when a DC (direct current) voltage is applied in the in-plane direction from above the dielectric thin film.

The optical waveguide component and the optical modulation component of the present disclosure are provided with a substrate with a dielectric thin film having a lithium niobate film that is resistant to cracking. Therefore, even if annealing is performed during the manufacturing process of the optical waveguide component and/or the optical modulation component, the lithium niobate film of the substrate with the dielectric thin film is resistant to cracking, and the productivity is excellent. Furthermore, since the lithium niobate film of the substrate with the dielectric thin film is resistant to cracking, the optical waveguide component and the optical modulation component have excellent durability.

### BRIEF DESCRIPTION OF THE DRAWINGS

FIG. 1 is a schematic cross-sectional view showing a substrate 1 with a dielectric thin film according to one embodiment of the present disclosure.

FIG. 2 is a plan view showing an example of an optical waveguide component 100 using the substrate 1 with a dielectric thin film shown in FIG. 1

FIG. 3 is a cross-sectional view of the optical waveguide component 100 shown in FIG. 2 taken along the line AA′.

FIG. 4 is a plan view showing an example of a Mach-Zehnder type optical modulation component 200A using the substrate 1 with the dielectric thin film shown in FIG. 1.

FIG. 5 is a cross-sectional view of the light modulation component 200A shown in FIG. 4 taken along the line BB′.

FIG. 6 is a graph showing the relationship between time and DC drift in the modulated waveform of the output light output from the optical modulation components 200A of Example 5, Example 10, and Comparative Example 3.

### DETAILED DESCRIPTION

The present inventors have conducted extensive research as described below in order to solve the above problems and to produce an optical modulation component in which cracks are unlikely to occur in a lithium niobate film and DC drift is suppressed in a substrate with a dielectric thin film having a lithium niobate film epitaxially grown on a single crystal substrate.

In a substrate with a dielectric thin film in which an epitaxially grown lithium niobate film is formed on and in contact with a single crystal substrate, large distortions and stresses are generated at the interface between the single crystal substrate and the lithium niobate film due to differences in lattice constants and linear expansion coefficients between the single crystal substrate and the lithium niobate film.

For this reason, in the conventional technology, in the manufacturing process of the substrate with the dielectric thin film, when the lithium niobate film is epitaxially grown, cracks tend to occur in the lithium niobate film. Furthermore, the thicker the lithium niobate film, the greater the above-mentioned distortion and stress, so that the thicker the lithium niobate film is, the more likely it is that cracks will occur in the lithium niobate film during and after the manufacturing process of the substrate with the dielectric thin film. Furthermore, when manufacturing an optical waveguide component and/or an optical modulation component using the substrate with the dielectric thin film, if a process such as annealing is performed, the distortion and stress caused by the difference in linear expansion coefficient between the single crystal substrate and the lithium niobate film tend to become larger. For this reason, when manufacturing an optical waveguide component and/or an optical modulation component using the substrate with the dielectric thin film, cracks tend to occur in the lithium niobate film during and after the manufacturing process.

The present inventors have proposed a method for suppressing the occurrence of cracks in a lithium niobate film by using a lithium niobate film made of an epitaxial film having a c-axis orientation having a twin crystal structure of LiNbO₃ including a first crystal and a second crystal corresponding to a crystal in which the first crystal is rotated 180° around the c-axis. In this case, the twin crystal structure relieves the distortion and stress caused by the difference in lattice constant and the difference in linear expansion coefficient between the single crystal substrate and the lithium niobate film. It is presumed that this makes it difficult for cracks to occur in the lithium niobate film.

However, in the optical modulation component using the lithium niobate film made of the epitaxial film having the above-mentioned twin crystal structure, it is difficult to suppress the DC drift.

Therefore, the inventors have conducted extensive research focusing on the relationship between the lithium niobate film consisting of an epitaxial film having the above-mentioned twin crystal structure and the DC drift that occurs when a DC (direct current) voltage is applied to an optical modulation component using the same.

As a result, it was found that by forming an optical modulation component using a dielectric thin film having a thickness of 0.5 μm to 2 μm, which is made of a lithium niobate film that is an epitaxial film having a c-axis orientation formed in contact with the main surface of a single crystal substrate, which has the above-mentioned twin crystal structure, and in which the first crystal and the second crystal in an upper region of the dielectric thin film, excluding a lower region from the single crystal substrate to half of a thickness direction in the dielectric film, have maximum domain widths of 80 nm to 300 nm, it is possible to suppress DC drift when a DC (direct current) voltage is applied in the in-plane direction from above the lithium niobate film. The reason for this is as follows.

In an optical modulation component using a lithium niobate film made of an epitaxial film having the above-mentioned twin crystal structure, it is difficult to control DC drift when a DC (direct current) voltage is applied, compared to an optical modulation component using a lithium niobate single crystal substrate.

This is presumably because, in the optical modulation component using the lithium niobate film made of the epitaxial film having the above-mentioned twin crystal structure, the modulation waveform that moves by applying a DC (direct current) voltage is affected by the crystal defects and/or dislocations present in the twin crystal structure. In the lithium niobate film made of the epitaxial film having the above-mentioned twin crystal structure, crystal defects and/or dislocations may exist at the boundary between the first crystal and the second crystal included in the above-mentioned twin crystal structure (hereinafter, sometimes referred to as “twin crystal boundary”).

In addition, in an optical modulation component having a substrate with a dielectric thin film having a lithium niobate film made of an epitaxial film having the above-mentioned twin crystal structure, when a DC (direct current) voltage is applied to the lithium niobate film in the in-plane direction, a DC (direct current) electric field moves near the surface of the lithium niobate film. At this time, if the median value (maximum domain width) of the measured values obtained by measuring the crystal domain widths that are widths in a direction perpendicular to a growth direction of each crystal and maximum dimension within the thickness direction of the dielectric thin film, for 10 or more arbitrary first crystals and second crystals present within a measurement region with a length of 4 μm in cross section, is 80 nm to 300 nm, the above-mentioned maximum domain width is sufficiently wide, thereby suppressing the number of twin boundaries crossed by the DC electric field.

Furthermore, when the first crystals and the second crystals in the upper region of the lithium niobate film have a maximum domain width of 80 nm to 300 nm, the maximum domain width is sufficiently narrow, so that the number of crystal defects and/or dislocations present in the first crystals and the second crystals is suppressed.

From these facts, it is estimated that when the first crystals and the second crystals in the upper region of the lithium niobate film have a maximum domain width of 80 nm to 300 nm, even if crystal defects and/or dislocations are present at each twin boundary, within the first crystals, and within the second crystals contained in the above-mentioned twin structure, the influence of the crystal defects and/or dislocations on the modulation waveform of the optical modulation component is suppressed.

Furthermore, since the first crystals and the second crystals in the upper region are within the above-mentioned maximum domain width range and the film thickness of the lithium niobate film is 0.5 μm to 2 μm, the influence of the DC electric field applied to the optical modulation component can be prevented from extending to the lower region of the lithium niobate film, and when the lithium niobate film is processed into a ridge shape to form an optical waveguide, the optical waveguide does not become an inappropriate shape.

As a result, it is estimated that an optical modulation component using a lithium niobate film having a film thickness of 0.5 μm to 2 μm and in which the first crystals and the second crystals in the upper region have a maximum domain width of 80 nm to 300 nm will have suppressed DC drift when a DC (direct current) voltage is applied in the in-plane direction from above the lithium niobate film.

Furthermore, the inventors manufactured an optical modulation component in which a signal electrode and a ground electrode are provided on a lithium niobate film having a film thickness of 0.5 μm to 2 μm and in which the first crystals and the second crystals in the upper region have a maximum domain width of 80 nm to 300 nm, and confirmed that cracks are unlikely to occur in the lithium niobate film and that DC drift is suppressed when a DC (direct current) voltage is applied in the in-plane direction from above the lithium niobate film, and thus conceived of the present disclosure.

The present disclosure includes the following aspects.

[1] A substrate with a dielectric thin film including:
a single crystal substrate; and
a dielectric thin film formed in contact with a main surface of the single crystal substrate, wherein
the dielectric thin film has a thickness of 0.5 μm to 2 μm and is made of a lithium niobate film that is an epitaxial film with a c-axis orientation,
the dielectric thin film has a twin crystal structure of LiNbO₃ of a first crystal and a second crystal corresponding to a crystal in which the first crystal is rotated 180° around the c-axis,
the first crystal and the second crystal in an upper region of the dielectric thin film, excluding a lower region from the single crystal substrate to half of a thickness direction in the dielectric film, have maximum domain widths of 80 nm to 300 nm,
the maximum domain widths of the first crystal and the second crystal are median values of measured values obtained by setting a measurement region having a length of 4 μm in a cross section at an arbitrary location on an interface between the dielectric thin film and the single crystal substrate and measuring crystal domain widths of 10 or more arbitrary first and second crystals present within the measurement region, each of the crystal domain widths being a crystal width in a direction perpendicular to a growth direction of each crystal and maximum dimension within the thickness direction.

[2] The substrate with a dielectric thin film according to [1], wherein a part or all of the first crystal and the second crystal in the dielectric thin film have non-uniform domain widths within the thickness direction.

[3] The substrate with a dielectric thin film according to [1], wherein the single crystal substrate is a sapphire single crystal substrate, the main surface of which is a c-plane.

[4] The substrate with a dielectric thin film according to [1], wherein the twin crystal structure of the dielectric thin film has a ratio of a first diffraction intensity corresponding to the first crystal to a second diffraction intensity corresponding to the second crystal of 0.5 or more and 2.0 or less in a pole figure measurement by an X-ray diffraction method.

[5] An optical waveguide component comprising a substrate with a dielectric thin film according to any one of [1] to [4].

[6] The optical waveguide component according to [5], including an optical waveguide made of the dielectric thin film.

[7] An optical modulation component comprising a substrate with a dielectric thin film according to any one of [1] to [4].

[8] The optical modulation component according to [7], further including: an optical wave guide made of the dielectric thin film; and a first electrode and a second electrode, both of which are configure to apply voltage in an in-plane direction from above the dielectric thin film, the voltage changing a refractive index of the optical waveguide.

The substrate with a dielectric thin film, the optical waveguide component, and the optical modulation component of the present embodiment will be described in detail below with reference to the drawings as appropriate. The drawings used in the following description may show characteristic parts in an enlarged scale for the sake of convenience in order to make the features of the present disclosure easier to understand. Therefore, the dimensional ratios of each component may differ from the actual ones. The materials, dimensions, etc. exemplified in the following description are merely examples, and the present disclosure is not limited to them, and may be modified as appropriate within the scope of the present disclosure.

[Substrate with a Dielectric Thin Film]

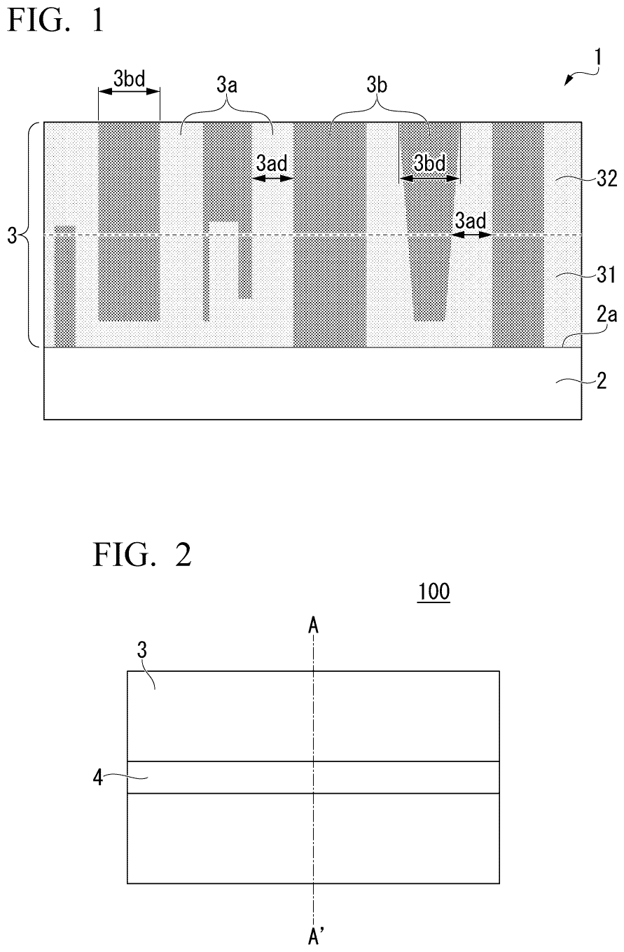

FIG. 1 is a schematic cross-sectional view showing a substrate with dielectric thin film 1 according to one embodiment of the present invention. As shown in FIG. 1, the substrate with dielectric thin film 1 of this embodiment has a single crystal substrate 2 and a dielectric thin film 3 formed on the main surface 2a of the single crystal substrate 2 in contact with the substrate.

### (Single Crystal Substrate 2)

The single crystal substrate 2 may be any substrate capable of growing an epitaxial film having a c-axis orientation having a twin crystal structure of lithium niobate (LiNbO₃), and any known single crystal substrate may be used. The single crystal substrate 2 preferably has a refractive index lower than that of lithium niobate, and may be, for example, a single crystal sapphire substrate or a single crystal silicon substrate.

In the substrate with dielectric thin film 1 of this embodiment, it is particularly preferable to use a single crystal sapphire substrate as the single crystal substrate 2. The single crystal substrate sapphire has a refractive index lower than that of LiNbO₃. Therefore, for example, when the dielectric thin film 3 of the substrate 1 with the dielectric thin film is used as an optical waveguide layer of an optical waveguide component and/or an optical modulation component, it can play the role of a cladding layer. Therefore, when the single crystal substrate 2 is a sapphire single crystal substrate, the dielectric thin film 3 can be suitably used as an optical waveguide layer of an optical waveguide component and/or an optical modulation component without providing a separate cladding layer between the single crystal substrate 2 and the dielectric thin film 3.

The dielectric thin film 3 formed on the single crystal substrate 2 of the substrate 1 with the dielectric thin film of this embodiment is likely to be formed as an epitaxial film having a c-axis orientation for the single crystal substrate 2 of various crystal orientations. Therefore, in the substrate 1 with the dielectric thin film of this embodiment, the crystal orientation of the single crystal substrate 2 is not particularly limited.

In the substrate 1 with the dielectric thin film of this embodiment, the dielectric thin film 3 is made of a lithium niobate film, which is an epitaxial film having a c-axis orientation, has a twin crystal structure of LiNbO₃, and has three-fold symmetry. For this reason, it is desirable that the crystal orientation of the main surface 2a of the single crystal substrate 2 has the same symmetry as the dielectric thin film 3. Therefore, when, for example, a sapphire single crystal substrate is used as the single crystal substrate 2, it is preferable that the main surface 2a is a c-plane. Also, when, for example, a silicon single crystal substrate is used as the single crystal substrate 2, it is preferable that the main surface 2a is a (111) plane.

### (Dielectric Thin Film 3)

The dielectric thin film 3 is made of a lithium niobate film, which is an epitaxial film oriented in the c-axis. The lithium niobate film forming the dielectric thin film 3 is mainly composed of lithium niobate (LiNbO₃). Lithium niobate has a large electro-optic constant, making it suitable as a material for the optical waveguide layer of an optical waveguide component and/or an optical modulation component.

The composition of the lithium niobate film forming the dielectric thin film 3 is expressed by the general formula LiₓN_{b}A_{y}O_{z} (A in the formula is an element other than Li, Nb, and O. x is 0.5 to 1.2, y is 0 to 0.5, and z is 1.5 to 4).

A in the formula represents an element other than Li, Nb, and O. Examples of elements represented by A include K, Na, Rb, Cs, Be, Mg, Ca, Sr, Ba, Ti, Zr, Hf, V, Cr, Mo, W, Fe, Co, Ni, Zn, Sc, and Ce. The element represented by A may be one type, or two or more types.

x in the formula is 0.5 to 1.2, and preferably 0.9 to 1.05.

y in the formula is 0 to 0.5.

In the formula, z is 1.5 to 4, preferably 2.5 to 3.5.

The lithium niobate film forming the dielectric thin film 3 has a twin crystal structure of LiNbO₃ including a first crystal 3a and a second crystal 3b corresponding to a crystal in which the first crystal is rotated 180° around the c-axis

The first crystal 3a and the second crystal 3b forming the dielectric thin film 3 are both close to single crystals. However, if the first crystal 3a and the second crystal 3b are too close to a complete single crystal, the effect of alleviating the strain and stress caused by the difference in lattice constant and the difference in linear expansion coefficient between the single crystal substrate 2 and the lithium niobate film forming the dielectric thin film 3 due to the above-mentioned twin crystal structure is reduced. For this reason, the lithium niobate film may be prone to cracks. Therefore, it is preferable that the half-width of the rocking curve of the (006) reflection measured by the X-ray diffraction method for both the first crystal 3a and the second crystal 3b is in the range of 0.3° or more and 0.6° or less. When the half-width of the rocking curve of the (006) reflection of the first crystal 3a and the second crystal 3b is within this range, the first crystal 3a and the second crystal 3b can be regarded as optically single crystals. Moreover, the first crystals 3a and the second crystals 3b are not too close to being completely single crystals, and the occurrence of cracks in the lithium niobate film can be effectively suppressed.

In the twin crystal structure of LiNbO₃ of the lithium niobate film forming the dielectric thin film 3, the ratio of the first diffraction intensity corresponding to the first crystal 3a to the second diffraction intensity corresponding to the second crystal 3b is preferably 0.5 or more and 2.0 or less, more preferably 0.8 or more and 1.25 or less, and more preferably closer to 1.0, in a pole figure measurement by X-ray diffraction method. In the pole figure measurement by the X-ray diffraction method, the ratio of the first diffraction intensity corresponding to the first crystal 3a to the second diffraction intensity corresponding to the second crystal 3b corresponds to the ratio of the first crystal 3a to the second crystal 3b.

The more uniform the ratio of the first crystal 3a to the second crystal 3b in the twin crystal structure of LiNbO₃ of the dielectric thin film 3, the more effectively the twin crystal structure can alleviate the distortion and stress caused by the difference in lattice constant and the difference in linear expansion coefficient between the single crystal substrate 2 and the lithium niobate film. Therefore, the lithium niobate film is less likely to crack.

The twin crystal structure of LiNbO₃ of the lithium niobate film forming the dielectric thin film 3 is preferably such that the first crystal 3a and the second crystal 3b are bonded to each other without a grain boundary. If a grain boundary exists at the boundary between the first crystal 3a and the second crystal 3b, light scattering occurs at the boundary surface. For this reason, when the dielectric thin film 3 of the substrate 1 with the dielectric thin film is used as an optical waveguide layer of an optical waveguide component and/or an optical modulation component, optical loss increases. In contrast, when the first crystal 3a and the second crystal 3b are joined to each other and no grain boundary exists at the boundary between them, the refractive index of both crystals is the same, so that no light scattering occurs. Therefore, the lithium niobate film can obtain optical properties equivalent to those of a single crystal.

The lithium niobate film forming the dielectric thin film 3 is desirably a single phase consisting of a twin crystal phase of LiNbO₃. It is preferable that the lithium niobate film forming the dielectric thin film 3 does not contain a different phase such as a LiNb₃O₈ phase or a Li₃NbO4 phase.

The thickness of the dielectric thin film 3 is 0.5 μm to 2 μm. Since the thickness of the dielectric thin film 3 is 0.5 μm or more, when the dielectric thin film 3 of the substrate 1 with the dielectric thin film is used as an optical waveguide layer of an optical modulation component, the influence of the DC electric field applied to the optical modulation component can be prevented from extending not only to the upper region 31 of the dielectric thin film 3 but also to the lower region 31. As a result, DC drift is suppressed. Furthermore, since the thickness of the dielectric thin film 3 is 0.5 μm or more, when the dielectric thin film 3 of the substrate 1 with the dielectric thin film is used as an optical waveguide layer of an optical modulation component, it is applicable to a wide range of light from visible light to infrared light.

In addition, since the thickness of the dielectric thin film 3 is 2 μm or less, when the dielectric thin film 3 of the substrate 1 with the dielectric thin film is processed into a ridge shape, the shape will not be inappropriate for the thickness of the dielectric thin film 3. Therefore, it is possible to suppress the influence on the DC drift characteristics due to an inappropriate shape of the optical waveguide 10 obtained by processing the dielectric thin film 3 into a ridge shape, and the DC drift is suppressed. In addition, since the thickness of the dielectric thin film 3 is 2 μm or less, it is possible to effectively suppress the occurrence of cracks in the lithium niobate film forming the dielectric thin film 3.

Moreover, the dielectric thin film 3 preferably has a “negative (−)” stress value, and is more preferably −80 MPa or less, and even more preferably −200 MPa or less, since this makes it difficult for cracks to occur in the lithium niobate film forming the dielectric thin film 3. Moreover, the stress value of the dielectric thin film 3 is more preferably −400 MPa or more, and even more preferably −300 MPa or more, and most preferably about −250 MPa, since this reduces the amount of warping of the substrate 1 with a dielectric thin film.

As shown in FIG. 1, the dielectric thin film 3 has a lower region 31 extending from the single crystal substrate 2 to half of a thickness direction in the dielectric thin film 3, and an upper region 32 of the dielectric thin film 3 excluding the lower region 31.

In the upper region 32, the median value (maximum domain width) of the measured values obtained by measuring the crystal domain widths 3ad, 3bd, which are the widths in the direction perpendicular to the growth direction of each crystal and the maximum dimensions within the thickness direction of the dielectric thin film, for any of 10 or more first crystals 3a and second crystals 3b present within a measurement region of 4 μm length in a cross-sectional view, is 80 nm to 300 nm. Therefore, in the optical modulation component including the substrate 1 with the dielectric thin film of this embodiment, even if crystal defects and/or dislocations are present at each twin boundary included in the twin structure of the dielectric thin film 3, it is presumed that the influence of the crystal defects and/or dislocations on the modulation waveform of the optical modulation component is suppressed.

In the substrate 1 with dielectric thin film of this embodiment, the median value of the measured values of the crystal domain widths 3ad, 3bd in the upper region 32 is 80 nm or more, so that the crystal domain widths 3ad, 3bd in the upper region 32 are sufficiently wide. Therefore, in an optical modulation component including the substrate 1 with dielectric thin film, when a DC (direct current) voltage is applied in the in-plane direction from above the dielectric thin film 3, the number of twin boundaries crossed by the DC electric field is suppressed. The median value (maximum domain width) of the measured values of the crystal domain widths 3ad, 3bd in the upper region 32 is preferably 100 nm or more.

In addition, in the substrate 1 with the dielectric thin film of this embodiment, the median value of the measured values of the crystal domain widths 3ad, 3bd in the upper region 32 is 300 nm or less, so that the crystal domain widths 3ad, 3bd in the upper region 32 are sufficiently narrow. Therefore, the number of crystal defects and/or dislocations present in the first crystal 3a and the second crystal 3b is suppressed. The median value (maximum domain width) of the measured values of the crystal domain widths 3ad, 3bd in the upper region 32 is preferably 250 nm or less, and more preferably 200 nm or less.

Furthermore, in the substrate 1 with the dielectric thin film of this embodiment, the shapes of the first crystals 3a and the second crystals 3b of the dielectric thin film 3 may be such that the median value of the measured values of the crystal domain widths 3ad, 3bd in the upper region 32 is 80 nm to 300 nm, and for example, the crystal domain widths 3ad, 3bd of the first crystals 3a and the second crystals 3b in the lower region 31 are not particularly limited.

In the optical modulation component including the substrate 1 with the dielectric thin film of this embodiment, even if a DC (direct current) voltage is applied in the in-plane direction from above the dielectric thin film 3, the DC electric field across the lower region 31 is small. Therefore, if the median value (maximum domain width) of the measured values of the crystal domain widths 3ad, 3bd in the first crystals 3a and the second crystals 3b in the upper region 32 is 80 nm to 300 nm, the influence of crystal defects and/or dislocations in the dielectric thin film 3 on the modulated waveform of the optical modulation component can be suppressed regardless of the maximum domain width in the first crystals 3a and the second crystals 3b in the lower region 31.

In the substrate 1 with the dielectric thin film of this embodiment, all of the first crystals 3a and second crystals 3b contained in the dielectric thin film 3 may have a uniform domain width in the thickness direction, or some or all of them may have a non-uniform domain width in the thickness direction, for example, as shown in FIG. 1.

Here, having a uniform domain means the difference between the maximum crystal width and the minimum crystal width is 15% or less with respect to the maximum crystal width. Having a non-uniform domain means the difference between the maximum crystal width and the minimum crystal width is more than 15% with respect to the maximum crystal width.

When all of the first crystals 3a and second crystals 3b in the dielectric thin film 3 have a uniform domain width in the thickness direction, the cross-sectional shapes of the first crystals 3a and second crystals 3b in a cross section of the dielectric thin film 3 cut in the thickness direction are rectangles with long sides the same as the thickness of the dielectric thin film 3. In this case, when the dielectric thin film 3 of the substrate 1 with dielectric thin film is used as an optical waveguide layer of an optical modulation component, the optical loss of the optical modulation component is smaller, which is preferable, compared to when some or all of the first crystals 3a and second crystals 3b have a non-uniform domain width in the thickness direction.

On the other hand, when some or all of the first crystals 3a and second crystals 3b contained in the dielectric thin film 3 have non-uniform domain widths in the thickness direction, it becomes easier to control the conditions for growing the dielectric thin film 3 on the single crystal substrate 2, and a substrate 1 with a dielectric thin film can be produced with good productivity, which is preferable, compared to when all of the first crystals 3a and second crystals 3b have uniform domain widths in the thickness direction.

When some or all of the first crystals 3a and the second crystals 3b contained in the dielectric thin film 3 have non-uniform domain widths in the thickness direction, the cross-sectional shape of the lower region 31 of the dielectric thin film 3 will be different from the cross-sectional shape of the upper region 32, as shown in FIG. 1.

When some or all of the first crystals 3a and the second crystals 3b in the dielectric thin film 3 have non-uniform domain widths in the thickness direction, the shapes of the first crystals 3a and/or the second crystals 3b in a cross section of the dielectric thin film 3 cut in the thickness direction are not particularly limited.

Therefore, the shape of the first crystal 3a and/or the second crystal 3b in a cross section in the thickness direction of the dielectric thin film 3 may be, for example, a trapezoid in which the interior angles at both ends of the base are equal or different from each other, or a triangle in which some or all of the three interior angles are different. Furthermore, the cross-sectional shape of the first crystal 3a and/or the second crystal 3b in a cross section in the thickness direction of the dielectric thin film 3 may be a symmetric shape or an asymmetric shape with respect to the domain width direction.

In addition, when the domain width in the thickness direction of the first crystals 3a and the second crystals 3b included in the dielectric thin film 3 is non-uniform in part or all, the first crystals 3a and/or the second crystals 3b may be formed continuously in the thickness direction of the dielectric thin film 3, or may not be formed continuously in the thickness direction of the dielectric thin film 3 in part or all. Therefore, at least a part of the first crystals 3a and/or the second crystals 3b may grow from an arbitrary position in the thickness direction of the dielectric thin film 3, or may stop growing at an arbitrary position in the thickness direction of the dielectric thin film 3. Therefore, at least a part of the first crystals 3a and/or the second crystals 3b may be present only in the lower region 31 or the upper region 32.

Furthermore, when some or all of the first crystals 3a and second crystals 3b contained in the dielectric thin film 3 have non-uniform domain widths in the thickness direction, at least a portion of the first crystals 3a and/or second crystals 3b may be split or branched at any position in the thickness direction of the dielectric thin film 3.

Furthermore, when some or all of the first crystals 3a and second crystals 3b contained in the dielectric thin film 3 have non-uniform domain widths in the thickness direction, the number of first crystals 3a and/or second crystals 3b may be different in the lower region 31 and the upper region 32.

In the substrate 1 with a dielectric thin film of this embodiment, the dielectric thin film 3 is an epitaxial film formed by epitaxial growth. Therefore, the crystal orientation of the lithium niobate film forming the dielectric thin film 3 is aligned with the crystal orientation of the underlying single crystal substrate 2. More specifically, when the film plane of the lithium niobate film forming the dielectric thin film 3 is defined as the X-Y plane and the film thickness direction is defined as the Z axis, the crystals of the single crystal substrate 2 and the crystals of the epitaxial film forming the dielectric thin film 3 are aligned with the X-axis, Y-axis, and Z-axis directions.

The fact that the dielectric thin film 3 is an epitaxial film can be proved, for example, firstly by confirming the peak intensity at the orientation position by 2θ-θ X-ray diffraction, and secondly by confirming the pole by pole figure measurement.

Specifically, in order to prove that the dielectric thin film 3 is an epitaxial film, the first condition is that when measured by 2θ-θ X-ray diffraction, all peak intensities other than the target plane must be 10% or less, preferably 5% or less, of the maximum peak intensity of the target plane. In the c-axis oriented epitaxial film forming the dielectric thin film 3, the peak intensities other than the (00L) plane must be 10% or less, preferably 5% or less, of the maximum peak intensity of the (00L) plane. (00L) is a general designation for equivalent planes such as (001) and (002).

The above-mentioned condition for confirming the peak intensity at the orientation position by 2θ-θ X-ray diffraction only indicates the orientation in one direction. Therefore, even if the above-mentioned first condition is satisfied, if the crystal orientation is not uniform within the plane, the intensity of the X-ray will not increase at a specific angle position and no pole will be observed.

Therefore, in order to prove that the dielectric thin film 3 is an epitaxial film, the second condition is that the poles must be visible in the pole figure measurement.

LiNbO₃ has a trigonal crystal structure, there are three poles of LiNbO₃ (014) in a single crystal. It is known that when a lithium niobate film is epitaxially grown, the epitaxial growth occurs in a so-called twin crystal state, in which crystals rotated 180° around the c-axis are symmetrically bonded. In this case, two of the three poles are symmetrically bonded, resulting in six poles.

In the substrate 1 with dielectric thin film of this embodiment, when a sapphire single crystal substrate having a c-plane as the main surface 2a is used as the single crystal substrate 2, the c-axis of the lithium niobate film forming the dielectric thin film 3 is preferably misaligned with the single crystal substrate 2 by 5° or less, and more preferably coincides with the dielectric thin film 3 (0°). If the c-axis misalignment between the dielectric thin film 3 and the single crystal substrate 2 is 5° or less, no practical problems will arise in the characteristics of the optical modulation component using the substrate 1 with dielectric thin film, due to the misalignment between the dielectric thin film 3 and the single crystal substrate 2.

[Method of Manufacturing Substrate with Dielectric Thin Film]

Next, an example of a method for manufacturing the substrate 1 with a dielectric thin film of this embodiment will be described. When manufacturing the substrate 1 with a dielectric thin film of this embodiment, for example, the dielectric thin film 3 is formed on the main surface 2a of the single crystal substrate 2 by using the method described below (dielectric thin film deposition step).

### (Dielectric Thin Film Deposition Process)

In the dielectric thin film deposition step, the dielectric thin film 3 is formed by epitaxial growth on the main surface 2a of the single crystal substrate 2. Examples of methods that can be used to form the dielectric thin film 3 include sputtering, vacuum deposition, pulsed laser ablation (PLD), chemical vapor deposition (CVD), and a sol-gel method.

Among the above methods, sputtering is preferred as the method for forming the dielectric thin film 3. This is because by forming the dielectric thin film 3 using the sputtering method, a single domain structure can be obtained in the as-formed state without any special treatment after film deposition. This is because the heat applied during sputtering and the electric field due to the self-bias also serve as a polarization process. If there is a distribution in the polarization, this will cause the electro-optic effect to decrease. With a single domain structure, it is possible to obtain an electro-optic coefficient similar to that of a single crystal.

When sputtering is used as a method for depositing the dielectric thin film 3, a target having a composition in the range of Li/(Li+Nb)=48% to 51%, for example, can be used.

The target can be produced, for example, by the following method. As the raw material, for example, a sintered body mainly composed of Li₂CO₃ and Nb₂O₅ with a purity of 3N or more is prepared. Next, the raw material is pulverized and mixed using a ball mill using balls made of ZrO₂ to obtain a target powder material. The obtained target powder material is sintered using a known method to obtain a target.

In the target manufacturing process, when the raw material is ground using the ball mill, balls made of ZrO₂ are scraped off. Therefore, several hundred ppm of Zr is mixed into the target powder obtained after the raw material is ground and mixed. Therefore, Zr is also mixed into the target obtained by sintering the target powder. However, since the amount of Zr contained in the target is small, the dielectric thin film 3 can be epitaxially grown on the main surface 2a of the single crystal substrate 2 by the sputtering method using the target containing Zr without any problems. Therefore, no problems occur due to Zr being mixed into the target.

The shape of the target used for depositing the dielectric thin film 3 is not particularly limited. The target is preferably circular with a planar area at least twice that of the single crystal substrate 2, so that a dielectric thin film 3 having a uniform thickness can be obtained. Furthermore, the deposition of the dielectric thin film 3 is preferably performed by arranging a circular target coaxially with the circular single crystal substrate 2, so that a dielectric thin film 3 having a uniform thickness can be obtained.

In the dielectric thin film deposition process of this embodiment, when sputtering is used as the deposition method, the O₂ ratio in the sputtering gas is increased, the gas pressure is set low, the temperature of the single crystal substrate 2 is set high, and the power is set low. This controls the domain width in the thickness direction of the first crystals 3a and the second crystals 3b in the upper region 32 of the dielectric thin film 3, which is made of a lithium niobate film that is an epitaxial film having a c-axis orientation and has a twin crystal structure of LiNbO₃.

Specifically, when a sputtering method is used as a method for forming the dielectric thin film 3, for example, a mixed gas of Ar and O₂ is used as the sputtering gas, the O₂ ratio in the sputtering gas is set to 35% to 60%, the gas pressure is set to 0.1 Pa to 0.5 Pa, the temperature of the single crystal substrate 2 is set to 450° C. to 700° C., and a power of 1500 W to 2000 W is applied, so that the film deposition rate is 500 nm/h to 600 nm/h.

As a result, a dielectric thin film 3 is obtained which is made of a lithium niobate film which is an epitaxial film oriented in the c-axis, has a twin crystal structure of LiNbO₃, and has an upper region 32 in which the median value (maximum domain width) of the measured values obtained by measuring crystal domain widths 3ad, 3bd of 10 or more arbitrary first crystals 3a and second crystals 3b present within a measurement region having a length of 4 μm in cross section is 80 nm to 300 nm.

It is preferable that the dielectric thin film 3 is formed in a so-called single step without changing the film forming conditions midway.

Through the above steps, the substrate 1 with the dielectric thin film of this embodiment is obtained.

The substrate 1 with a dielectric thin film of this embodiment is made of a lithium niobate film that is an epitaxial film having a c-axis orientation formed on and in contact with the main surface 2a of the single crystal substrate 2, and has a dielectric thin film 3 that has a twin crystal structure of LiNbO₃. Therefore, in the substrate 1 with a dielectric thin film of this embodiment, cracks are less likely to occur in the lithium niobate film that forms the dielectric thin film 3.

Moreover, in the substrate 1 with the dielectric thin film of this embodiment, the upper region 32 of the dielectric thin film 3 has a median value (maximum domain width) of the measured values obtained by measuring the crystal domain widths 3ad, 3bd of arbitrary 10 or more first crystals 3a and second crystals 3b present within a measurement region having a length of 4 μm in cross section, which is 80 nm to 300 nm, and the film thickness of the dielectric thin film 3 is 0.5 μm to 2 μm. Therefore, the optical modulation component having a signal electrode and a ground electrode provided on the dielectric thin film 3 of the substrate 1 with the dielectric thin film of this embodiment has suppressed DC drift when a DC (direct current) voltage is applied in the in-plane direction from above the dielectric thin film 3.

### [Optical Waveguide Component]

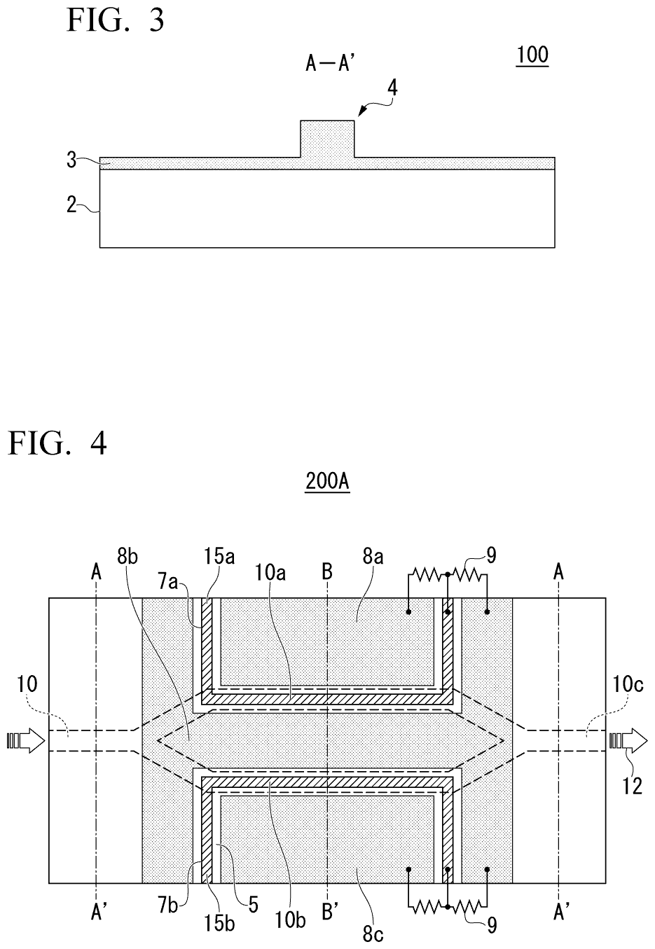

FIG. 2 is a plan view showing an example of an optical waveguide component 100 using the substrate 1 with dielectric thin film shown in FIG. 1. FIG. 3 is a cross-sectional view taken along the line A-A′ of the optical waveguide component 100 shown in FIG. 2. In the optical waveguide component 100 shown in FIGS. 2 and 3, the same reference numerals are used for the members of the substrate 1 with dielectric thin film shown in FIG. 1, and the description thereof will be omitted.

The optical waveguide component 100 shown in FIGS. 2 and 3 has an optical waveguide consisting of a ridge portion 4 formed by processing the dielectric thin film 3 of the substrate 1 with dielectric thin film shown in FIG. 1 into a ridge shape (convex shape). The ridge portion 4 of the optical waveguide component 100 is a portion through which the target light propagates in the TM fundamental mode. The optical waveguide component 100 shown in FIGS. 2 and 3 can be manufactured by processing the dielectric thin film 3 of the substrate 1 with dielectric thin film shown in FIG. 1 into a ridge shape (convex shape). The method for processing the dielectric thin film 3 into a ridge shape can be a known method such as an etching method.

The optical waveguide component 100 shown in FIGS. 2 and 3 includes the substrate 1 with the dielectric thin film shown in FIG. 1. Therefore, cracks are unlikely to occur in the lithium niobate film forming the dielectric thin film 3 of the substrate 1 with the dielectric thin film, and productivity is excellent. In addition, cracks are unlikely to occur in the lithium niobate film forming the dielectric thin film 3 of the substrate 1 with the dielectric thin film, and therefore the optical waveguide component 100 has excellent durability. Furthermore, the optical waveguide component 100 of this embodiment can form an optical modulation component in which DC drift is suppressed when a DC (direct current) voltage is applied in the in-plane direction from above the dielectric thin film 3 of the substrate 1 with the dielectric thin film.

### [Light Modulation Component]

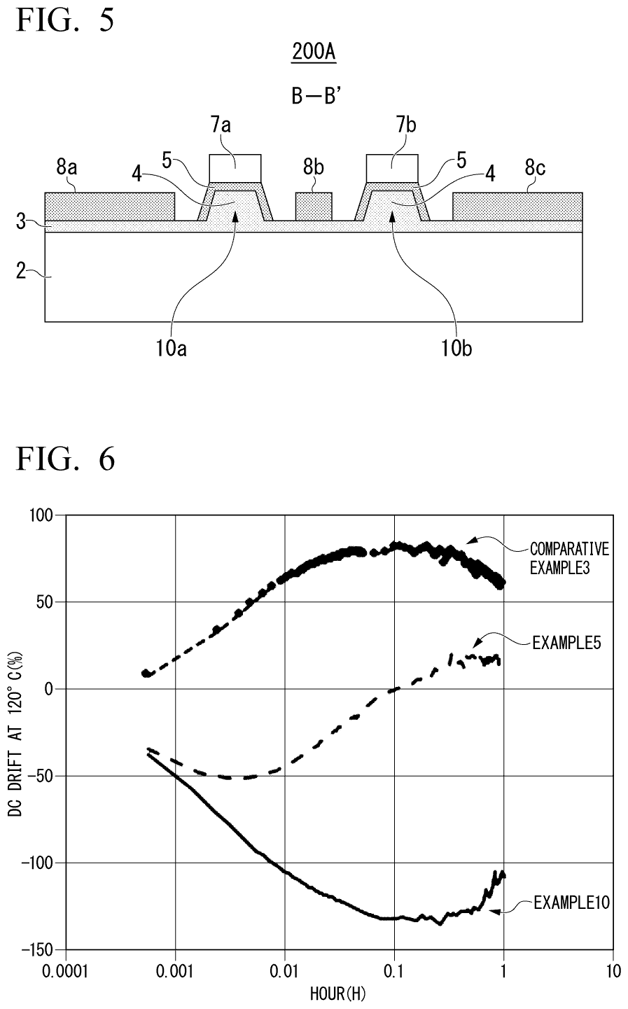

FIG. 4 is a plan view showing an example of a Mach-Zehnder type optical modulation component 200A using the substrate 1 with the dielectric thin film shown in FIG. 1. FIG. 5 is a cross-sectional view taken along line B-B′ of the optical modulation component 200A shown in FIG. 4. The cross-sectional view taken along line A-A′ of the optical modulation component 200A shown in FIG. 4 is the same as the cross-sectional view of the optical waveguide component 100 shown in FIG. 3.

In the optical modulation component 200A shown in FIGS. 4 and 5, the same reference numerals are used to designate the members of the substrate 1 with the dielectric thin film shown in FIG. 1, and the description thereof will be omitted.

The optical modulation component 200A shown in FIGS. 4 and 5 is a device that applies a voltage to a Mach-Zehnder interferometer formed by an optical waveguide 10 to modulate the light propagating through the optical waveguide 10. As shown in FIG. 4, the optical waveguide 10 has a first optical waveguide 10a and a second optical waveguide 10b branched from a single input optical waveguide, and an output optical waveguide 10c in which the first optical waveguide 10a and the second optical waveguide 10b are combined.

As shown in FIGS. 4 and 5, two first electrodes 7a and 7b are provided on the first optical waveguide 10a and the second optical waveguide 10b, respectively. Therefore, the light modulation component 200A has a dual electrode structure. The first electrodes 7a and 7b may be made of, for example, an Au film or a laminated film of a Ti film and an Au film.

The optical modulation component 200A shown in FIGS. 4 and 5 has a ridge portion 4 formed by processing the dielectric thin film 3 in the substrate 1 with the dielectric thin film shown in FIG. 1 into a ridge shape (convex shape). In the optical modulation component 200A, the ridge portion 4 forms an optical waveguide 10. As shown in FIG. 5, a first electrode 7a is formed on the ridge portion 4 constituting the first optical waveguide 10a of the optical waveguide 10 via a buffer layer 5. Also, a first electrode 7b is formed on the ridge portion 4 constituting the second optical waveguide 10b of the optical waveguide 10 via a buffer layer 5. As shown in FIG. 5, the buffer layer 5 is formed so as to cover the upper surface and side surface of the ridge portion 4. As the buffer layer 5, for example, a layer made of a SiO₂ film or a layer made of a thin film obtained by adding an oxide of a metal element to SiO₂ can be used.

As shown in FIGS. 4 and 5, the second electrodes 8a, 8b, 8c are provided at a distance from each other via the first electrodes 7a, 7b. The second electrodes 8a, 8b, 8c are formed in contact with the upper surface of the slab portion made of the dielectric thin film 3. For example, the second electrodes 8a, 8b, 8c may be made of an Au film or a laminated film of a Ti film and an Au film. The first electrodes 7a, 7b and the second electrodes 8a, 8b, 8c apply a voltage that changes the refractive index of the first optical waveguide 10a and the second optical waveguide 10b of the optical waveguide 10 in the in-plane direction from above the dielectric thin film 3.

The slab portion made of the dielectric thin film 3 is formed by thinning a part of the upper surface of the dielectric thin film 3 in the substrate 1 with the dielectric thin film shown in FIG. 1 by etching or the like. As shown in FIG. 4, the first electrodes 7a, 7b and the second electrodes 8a, 8b, 8c are connected by a terminating resistor 9.

### [Method of Manufacturing Light Modulation Component]

The light modulation component 200A shown in FIGS. 4 and 5 can be manufactured, for example, by the manufacturing method described below.

First, the dielectric thin film 3 in the substrate 1 with a dielectric thin film shown in FIG. 1 is processed into a ridge shape (convex shape) by a known method such as an etching method to form an optical waveguide 10 consisting of a ridge portion 4 and a slab portion consisting of the dielectric thin film 3.

Next, a buffer layer 5 is formed so as to cover the top and side surfaces of the ridge portion 4 by using a known method such as sputtering, vacuum deposition, pulsed laser ablation (PLD) or chemical vapor deposition (CVD).

Thereafter, using a known method such as sputtering or vacuum deposition, second electrodes 8a, 8b, and 8c are formed in contact with the upper surface of the slab portion made of the dielectric thin film 3, and first electrodes 7a and 7b are formed on the buffer layer 5.

Through the above steps, the light modulation component 200A shown in FIGS. 4 and 5 is obtained.

### [Operation Principle of Light Modulation Component]

Next, the operation principle of the optical modulation component 200A will be explained.

As shown in FIG. 4, the two first electrodes 7a, 7b and the second electrodes 8a, 8b, 8c are connected by a termination resistor 9 to function as traveling wave electrodes. The first electrodes 7a, 7b are used as signal electrodes, and the second electrodes 8a, 8b, 8c are used as ground electrodes. Then, so-called complementary signals, which have the same absolute value and different positive and negative phases, are input to the two first electrodes 7a, 7b from the input sides 15a, 15b of the first electrodes 7a, 7b of the optical modulation component 200A.

In this embodiment, when a signal is input from the input side 15a, 15b, a DC (direct current) voltage is applied in a superimposed manner in the in-plane direction of the dielectric thin film 3 from the first electrodes 7a, 7b toward the second electrodes 8a, 8b, 8c. This causes the refractive indexes of the first optical waveguide 10a and the second optical waveguide 10b of the optical waveguide 10 to change in proportion to the DC voltage, and output light having a modulated waveform is output from the output optical waveguide 10c. The modulated waveform of the output light output from the optical modulation component 200A changes with the passage of time during which the DC (direct current) voltage is applied. This change in the modulated waveform over time is called DC drift.

The lithium niobate film forming the dielectric thin film 3 in the substrate 1 with the dielectric thin film has an electro-optic effect. Therefore, the refractive indexes of the first optical waveguide 10a and the second optical waveguide 10b change to +Δn and −Δn, respectively, depending on the DC (direct current) voltage applied to the first optical waveguide 10a and the second optical waveguide 10b. As a result, the phase difference between the first optical waveguide 10a and the second optical waveguide 10b changes. Signal light having a modulated waveform that is intensity-modulated by this change in phase difference is output to the output side 12 from the output optical waveguide 10c where the first optical waveguide 10a and the second optical waveguide 10b are combined.

The light modulation component 200A of this embodiment includes a substrate 1 with a dielectric thin film as shown in FIG. 1. Therefore, the light modulation component 200A of this embodiment is less susceptible to cracks in the lithium niobate film forming the dielectric thin film 3 of the substrate 1 with a dielectric thin film, and is excellent in productivity and durability. The light modulation component 200A of this embodiment also includes a substrate 1 with a dielectric thin film as shown in FIG. 1. Therefore, the first electrodes 7a, 7b and the second electrodes 8a, 8b, 8c suppress DC drift when a DC (direct current) voltage is applied in the in-plane direction from above the dielectric thin film 3. Therefore, the light modulation component 200A of this embodiment is excellent in reliability and can be suitably used, for example, as an optical communication device.

The optical modulation component 200A of this embodiment is preferably such that, when heated to 120° C. and a signal is input from the input sides 15a and 15b of the first electrodes 7a and 7b, a DC (direct current) voltage is applied in a superimposed manner from the first electrodes 7a and 7b toward the second electrodes 8a, 8b and 8c in the in-plane direction of the dielectric thin film 3, the DC drift does not exceed 50% before one hour has elapsed. The DC drift is a numerical value calculated using the following formula (I).

$$DC drift ( \% ) = ( shift voltage ( V ) / applied DC voltage ( V ) ) \times 100 \qquad ( I )$$

(In formula (I), the shift voltage (V) is a DC (direct current) voltage that indicates the amount of phase shift (drift amount) of the modulated waveform relative to the modulated waveform at the time when the DC (direct current) voltage is applied.)

In the case where the above-mentioned DC drift of the light modulation component 200A of this embodiment does not exceed 50% before exceeding one hour when heated to 120° C., the DC drift can be easily suppressed. This is because the light modulation component 200A is provided with a feedback driver (control circuit) that controls the DC (direct current) voltage applied from the first electrodes 7a, 7b to the second electrodes 8a, 8b, 8c, and the feedback driver applies a DC voltage corresponding to the shift voltage (V), thereby easily compensating for the shift amount of the phase of the modulation waveform.

Although the preferred embodiment of the present disclosure has been described above, the present disclosure is not limited to the above embodiment. The present disclosure can be modified in various ways without departing from the spirit of the present disclosure, and it goes without saying that such modifications are also included within the scope of the present disclosure.

### EXAMPLES

### Examples (Ex.) 1 to 13, Comparative Examples (C.Ex.) 1 to 6

The substrate 1 with the dielectric thin film shown in FIG. 1 was produced by the method described below.

As the single crystal substrates 2, 4-inch sapphire single crystal substrates having a c-plane as the main surface 2a were prepared.

### (Dielectric Thin Film Deposition Process)

In the dielectric thin film deposition step, the dielectric thin film 3 was deposited on the main surface 2a of the single crystal substrate 2 by epitaxial growth using a sputtering method.

The target used was a circle having a diameter of 8 inches and a composition of Li/(Li+Nb)=50%.

The target was prepared by the following method. A sintered body mainly composed of Li₂CO₃ and Nb₂O₅ with a purity of 3N or more was prepared as a raw material. Next, the raw material was pulverized and mixed using a ball mill using balls made of ZrO₂ to obtain a target powder. The obtained target powder was sintered to obtain a target.

The dielectric thin film 3 was deposited by arranging the target thus obtained coaxially with the single crystal substrate 2 so that the distance from the main surface 2a of the single crystal substrate 2 was 110 mm.

The dielectric thin film 3 was deposited by using a mixed gas of Ar and O₂ as the sputtering gas, setting the O₂ ratio in the sputtering gas to 35% to 60%, the gas pressure to 0.1 Pa to 0.5 Pa, setting the temperature of the single crystal substrate 2 to 450° C. to 700° C., and applying a power of 1500 W to 2000 W so that the film deposition rate was 500 nm/h to 600 nm/h.

The dielectric thin film 3 was deposited in a so-called single step without changing the film forming conditions during the process.

By the above steps, the substrates 1 with the dielectric thin film of Examples 1 to 13 and Comparative Examples 1 to 6 were obtained.

### Example 14

A substrate with a dielectric thin film was produced in the same manner as in Example 8, except that the deposition time of the dielectric thin film 3 was shortened.

### Example 15

A substrate with a dielectric thin film was produced in the same manner as in Example 8, except that the deposition time of the dielectric thin film 3 was increased.

### Comparative Example 7

A substrate with a dielectric thin film was produced in the same manner as in Example 8, except that the deposition time of the dielectric thin film 3 was shortened.

### Comparative Example 8 and Comparative Example 9

A substrate with a dielectric thin film was produced in the same manner as in Example 8, except that the deposition time of the dielectric thin film 3 was increased.

For the thus obtained substrates with dielectric thin films of Examples 1 to 15 and Comparative Examples 1 to 9, the dielectric thin films 3 were confirmed to be epitaxial films by the above-mentioned methods, firstly, by confirming the peak intensity at the orientation position by 2θ-θ X-ray diffraction, and secondly, by confirming the poles by pole figure measurement.

Furthermore, for the substrates with dielectric thin films of Examples 1 to 15 and Comparative Examples 1 to 9, whether or not the dielectric thin films 3 have a twin crystal structure of LiNbO₃ was examined by the method described below. As a result, it was confirmed that the dielectric thin films 3 of the substrates with dielectric thin films of Examples 1 to 15 and Comparative Examples 1 to 9 all have a twin crystal structure of LiNbO₃.

Method for Confirming that LiNbO₃ has a Twin Crystal Structure

A cross section of the substrate with the dielectric thin film cut in the thickness direction was observed using a transmission electron microscope (TEM) (manufactured by FEI) to obtain a dark field (DF) image. At this time, the beam incidence conditions were adjusted so that the image of either the first crystal 3a or the second crystal 3b contained in the twin crystal structure of LiNbO₃ forming the dielectric thin film 3 was in a high contrast (bright) state.

In the dark field image obtained by adjusting the beam incidence conditions as described above, when the dielectric thin film 3 has a twin crystal structure of LiNbO₃, one of the first crystal 3a and the second crystal 3b has a high contrast (bright) image and the other has a low contrast (dark) image, so that the first crystal 3a and the second crystal 3b can be clearly distinguished. This confirmed that the dielectric thin film 3 has a twin crystal structure of LiNbO₃.

Furthermore, for these obtained substrates with dielectric thin films of Examples 1 to 15 and Comparative Examples 1 to 9, the following were examined by the methods described below: Whether the dielectric thin film 3 is a single layer of LiNbO₃; whether the domain width of the dielectric thin film 3 is uniform; the maximum domain width of the first crystals 3a and the second crystals 3b of the dielectric thin film 3; the film thickness of the dielectric thin film 3; and the ratio of the first diffraction intensity corresponding to the first crystals 3a and the second diffraction intensity corresponding to the second crystals 3b. The results are shown in Tables 1 and 2.

Tables 1 and 2 show the types of single crystal substrates 2 used in the substrates with dielectric thin films in Examples 1 to 15 and Comparative Examples 1 to 9.

TABLE 1

| | | Maximum | | | Ratio of the | |
|---|---|---|---|---|---|---|
| | | domain | | | first diffraction | |
| | | width of | | | intensity | |
| | | the first | | | corresponding | |
| | | crystal 3a | | | to the first | |
| | | and the | Domain | | crystal to the | |
| | Dielectric | second | width of the | Film | second | |
| | thin film | crystal 3b | dielectric | thickness | diffraction | |
| | being | of the | thin film | of the | intensity | |
| | single | dielectric | being | dielectric | corresponding | Single |
| | layer or | thin film | uniform or | thin film | to the second | crystal |
| | not | (nm) | not | (μm) | crystal | substrate |
| Ex. 1 | Single | 80 | Non-uniform | 1.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 2 | Single | 93 | Non-uniform | 1.5 | 1.04 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 3 | Single | 106 | Non-uniform | 1.5 | 1.04 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 4 | Single | 111 | Non-uniform | 1.5 | 1.08 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 5 | Single | 118 | Non-uniform | 1.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 6 | Single | 120 | Non-uniform | 1.5 | 0.92 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 7 | Single | 130 | Non-uniform | 1.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 8 | Single | 135 | Non-uniform | 1.5 | 0.92 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 9 | Single | 158 | Non-uniform | 1.5 | 0.96 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 10 | Single | 197 | Non-uniform | 1.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 11 | Single | 220 | Non-uniform | 1.5 | 0.96 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 12 | Single | 262 | Non-uniform | 1.5 | 0.96 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 13 | Single | 300 | Non-uniform | 1.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 14 | Single | 135 | Non-uniform | 0.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| Ex. 15 | Single | 135 | Non-uniform | 2.0 | 1.04 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |

TABLE 2

| | | Maximum | | | Ratio of the | |
|---|---|---|---|---|---|---|
| | | domain | | | first diffraction | |
| | | width of | | | intensity | |
| | | the first | | | corresponding | |
| | | crystal 3a | | | to the first | |
| | | and the | Domain | | crystal to the | |
| | Dielectric | second | width of the | Film | second | |
| | thin film | crystal 3b | dielectric | thickness | diffraction | |
| | being | of the | thin film | of the | intensity | |
| | single | dielectric | being | dielectric | corresponding | Single |
| | layer or | thin film | uniform or | thin film | to the second | crystal |
| | not | (nm) | not | (μm) | crystal | substrate |
| C. Ex. 1 | Single | 68 | Non-uniform | 1.5 | 0.92 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 2 | Single | 70 | Non-uniform | 1.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 3 | Single | 75 | Non-uniform | 1.5 | 1.08 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 4 | Single | 337 | Non-uniform | 1.5 | 1.04 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 5 | Single | 361 | Non-uniform | 1.5 | 1.04 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 6 | Single | 367 | Non-uniform | 1.5 | 1.00 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 7 | Single | 135 | Non-uniform | 0.3 | 0.96 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 8 | Single | 135 | Non-uniform | 2.2 | 0.96 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |
| C. Ex. 9 | Single | 135 | Non-uniform | 2.5 | 0.96 | Sapphire |
| | layer | | | | | single |
| | | | | | | crystal |
| | | | | | | substrate, |
| | | | | | | the main |
| | | | | | | surface of |
| | | | | | | which is |
| | | | | | | c-plain |

### Whether the Dielectric Thin Film 3 is a Single Layer of LiNbO₃ or not

The refractive index of the lithium niobate film, which is the dielectric thin film 3 of the substrate 1 with the dielectric thin film, was measured using a prism coupler (manufactured by Metricon) to measure the Li content contained in the lithium niobate film. When the content of Li₂O contained in the lithium niobate film is within the range of 47.5 mol % to 50.0 mol %, the lithium niobate film is considered to be a single phase of LiNbO₃. By using a method for measuring the content of Li₂O contained in the lithium niobate film using the refractive index of the lithium niobate film measured using a prism coupler, the Li content contained in the lithium niobate film, which is the dielectric thin film 3 of the substrate 1 with the dielectric thin film, can be measured with high accuracy in a non-destructive manner.

First, a lithium niobate single crystal substrate with a Li content of 47.5 mol % and a lithium niobate single crystal substrate with a Li content of 50.0 mol % were prepared, and the refractive index was measured using a prism coupler. The refractive index measured using a prism coupler changes almost in proportion to the Li content. For this reason, a calibration curve was created using the refractive indexes measured using a prism coupler for a lithium niobate single crystal substrate with a Li content of 47.5 mol % and a lithium niobate single crystal substrate with a Li content of 50.0 mol %, and the Li content (content) contained in the lithium niobate film, which is the dielectric thin film 3 of each of the dielectric thin film-attached substrates 1 of Examples 1 to 15 and Comparative Examples 1 to 9, was calculated using this calibration curve.

All of the lithium niobate films of the dielectric thin film-attached substrates 1 of Examples 1 to 15 and Comparative Examples 1 to 9 contained 47.5 mass % to 49.8 mass % Li. Based on this result, it was confirmed that the lithium niobate films of the dielectric thin film-attached substrates 1 of Examples 1 to 15 and Comparative Examples 1 to 9 all were a single phase of LiNbO₃ containing no heterogeneous phase.

### Whether the Domain Width of the Dielectric Thin Film 3 is Uniform; Maximum Domain Width of the First Crystals 3a and the Second Crystals 3b of the Dielectric Thin Film 3

A cross section of the dielectric thin film 3 of the substrate 1 with the dielectric thin film cut in the thickness direction was observed using a transmission electron microscope (TEM) (manufactured by FEI) to obtain a dark field (DF) image. At this time, the beam incidence conditions were adjusted so that the image of either the first crystal 3a or the second crystal 3b contained in the twin crystal structure of LiNbO₃ forming the dielectric thin film 3 was in a high contrast (bright) state. As a result, a dark field image was obtained in which the image of either the first crystal 3a or the second crystal 3b was in a high contrast (bright) state and the image of the other was in a low contrast (dark) state. Therefore, the obtained dark field image clearly distinguished the first crystal 3a and the second crystal 3b.

The dark field images thus obtained were subjected to image analysis to check whether the domain widths of the first crystals 3a and the second crystals 3b present on the interface of the 4 μm long single crystal substrate 2 were uniform. If the domain shape was a rectangular, so-called columnar shape, the domain width was evaluated as “Uniform”, and if other domain shapes were also present, the domain width was evaluated as “Non-uniform.” It was confirmed that the lithium niobate films of the substrates 1 with the dielectric thin films of Examples 1 to 15 and Comparative Examples 1 to 9 had non-uniform domain widths.

Moreover, the above dark field image was subjected to image analysis to determine the maximum domain width of the first crystals 3a and the second crystals 3b contained in the upper region 32 of the dielectric thin film 3 by the method described below.

A measurement region having a length of 4 μm in cross section was set at an arbitrary location on the interface between the dielectric thin film 3 and the single crystal substrate 2 in the above dark field image, and the crystal domain widths of any of 10 or more first crystals 3 a and second crystals 3 b present within the measurement region were measured, and the median value of the obtained measurements was determined as the maximum domain width.

Here, the crystal domain width of each of the first crystals 3a and each of the second crystals 3b is the domain width of each of the first crystals 3a and each of the second crystals 3b measured in a direction perpendicular to the growth direction of each crystal, and is the length dimension of the domain width at the thickest (in other words, the widest) point within the thickness direction of the dielectric thin film 3.

In addition, in the measurement region, where the crystal domain width is measured to examine the maximum domain width, there is no need to distinguish between the first crystals 3a and the second crystals 3b among the 10 or more arbitrary first crystals 3a and second crystals 3b. Therefore, the ratio between the number of the first crystals 3a and the number of the second crystals 3b for which the crystal domain width is measured is not particularly limited, and it is sufficient that the total number of the first crystals 3a and the number of the second crystals 3b for which the crystal domain width is measured is 10 or more.

### Thickness of Dielectric Thin Film 3

The thickness of the dielectric thin film 3 in the substrate 1 with the dielectric thin film was determined by performing high-resolution analysis using a scanning transmission electron microscope (STEM) (manufactured by FEI) to measure the thickness of the dielectric thin film 3 at 10 or more points within a rectangular field of view of 1.3 μm in length and 4 μm in width, and calculating the median value. Ratio of the first diffraction intensity corresponding to the first crystals 3a to the second diffraction intensity corresponding to the second crystals 3b of the dielectric thin film 3

For the dielectric thin film 3 of the substrate 1 with the dielectric thin film, pole figure measurement was performed by X-ray diffraction using an X-ray diffractometer (manufactured by Rigaku Corporation) to measure a first diffraction intensity corresponding to the first crystals 3a and a second diffraction intensity corresponding to the second crystals 3b of the dielectric thin film 3. Using the results, the ratio of the first diffraction intensity to the second diffraction intensity was calculated.

Furthermore, for the substrates with dielectric thin film of Examples 1 to 15 and Comparative Examples 1 to 9, the stress in the dielectric thin film; the presence or absence of cracks in the dielectric thin film 3; and the presence or absence of cracks caused by annealing, were examined by the methods described below. The results are shown in Tables 3 and 4.

TABLE 3

| | | | | Presence or | |
|---|---|---|---|---|---|
| | | | | absence of | |
| | | | Presence or | cracks in the | |
| | Kind of | Stress in the | absence of | dielectric | |
| | stress in | dielectric | cracks in the | thin film | |
| | dielectric | thin film | dielectric | formed by | |
| | thin film | (MPa) | thin film | annealing | DC drift evaluation |
| Ex. 1 | Compressive stress | −120 | Absent | Absent | Pass |
| Ex. 2 | Compressive | −154 | Absent | Absent | Pass |
| | stress | | | | |
| Ex. 3 | Compressive | −197 | Absent | Absent | Pass |
| | stress | | | | |
| Ex. 4 | Compressive | −203 | Absent | Absent | Pass |
| | stress | | | | |
| Ex. 5 | Compressive | −212 | Absent | Absent | Pass |
| | stress | | | | |
| Ex. 6 | Compressive | −222 | Absent | Absent | Pass |
| | stress | | | | |
| Ex. 7 | Compressive | −227 | Absent | Absent | Pass |
| | stress | | | | |
| Ex. 8 | Compressive | −235 | Absent | Absent | Pass |
| | stress | | | | |
| Ex. 9 | Compressive | −250 | Absent | Absent | Pass |
| | stress | | | | |
| Ex. 10 | Compressive | −264 | Absent | Absent | Pass |
| | stress | | | | |
| Ex. 11 | Compressive | −271 | Absent | Absent | Pass |
| | stress | | | | |
| Ex. 12 | Compressive | −297 | Absent | Absent | Pass |
| | stress | | | | |
| Ex. 13 | Compressive | −320 | Absent | Absent | Pass |
| | stress | | | | |
| Ex. 14 | Compressive | −685 | Absent | Absent | Pass |
| | stress | | | | |
| Ex. 15 | Compressive | −192 | Absent | Absent | Pass |
| | stress | | | | |

TABLE 4

| | | | | Presence or | |
|---|---|---|---|---|---|
| | | | Presence or | absence of | |
| | | Stress in the | absence of | cracks in the | |
| | Kind of stress | dielectric | cracks in the | dielectric thin | |
| | in dielectric | thin film | dielectric | film formed | |
| | thin film | (MPa) | thin film | by annealing | DC drift evaluation |
| C.Ex. 1 | Compressive stress | −15 | Present | Present | Could not |
| | | | | | evaluate |
| C.Ex. 2 | Compressive | −50 | Present | Present | Could not |
| | stress | | | | evaluate |
| C.Ex. 3 | Compressive | −82 | Absent | Absent | Fail |
| | stress | | | | |
| C.Ex. 4 | Compressive | −348 | Absent | Absent | Fail |
| | stress | | | | |
| C.Ex. 5 | Compressive | −419 | Absent | Absent | Fail |
| | stress | | | | |
| C.Ex. 6 | Compressive | −441 | Absent | Absent | Fail |
| | stress | | | | |
| C.Ex. 7 | Compressive | −946 | Absent | Absent | Fail |
| | stress | | | | |
| C.Ex. 8 | Compressive | −170 | Absent | Absent | Fail |
| | stress | | | | |
| C.Ex. 9 | Compressive | −148 | Absent | Absent | Fail |
| | stress | | | | |

### Stress in the Thin Dielectric Film

The amount of warping of the dielectric thin film 3 in the substrate 1 with the dielectric thin film was measured using a needle-type step gauge (manufactured by KLA-Tenchore Corporation), and the stress of the dielectric thin film was calculated by Stoney's formula.

When the stress value of the obtained dielectric thin film was plus (+), it was evaluated as tensile stress. When the stress value of the dielectric thin film was minus (−), it was evaluated as compressive stress. When the stress value of the dielectric thin film was −400 MPa to −80 MPa, it was regarded as no cracks occurred and the amount of warping of the substrate with the dielectric thin film was small, so the stress was evaluated to be within a suitable range.

### Presence or Absence of Cracks in Dielectric Thin Film 3

The substrate with the dielectric thin film was observed using an optical microscope (manufactured by Olympus) with an objective lens magnification of 20 times and a field of view diameter of about 0.5 mm, and an objective lens magnification of 100 times and a field of view diameter of about 0.1 mm, to check for the presence or absence of cracks in the dielectric thin film 3.

When no cracks were found under the condition explained above, the sample was evaluated as absent of cracks. When even one crack was found, the sample was evaluated as present of cracks.

### Whether or not Cracks Occur in the Dielectric Thin Film 3 Due to Annealing

The substrate 1 with the dielectric thin film was annealed in an oxygen atmosphere at a pressure of 1 atmosphere at 600° C. for 1 hour.

Thereafter, the presence or absence of cracks in the dielectric thin film 3 after annealing was examined and evaluated in the same manner as in the above-mentioned the presence or absence of cracks in the dielectric thin film 3.

### [Manufacturing of Optical Modulation Component]

The optical modulation component 200A shown in FIGS. 4 and 5 was manufactured using the substrates 1 with dielectric thin films of Examples 1 to 15 and Comparative Examples 1 to 9, respectively, by the manufacturing method shown below. The dielectric thin film 3 on the substrate 1 with dielectric thin film was processed into a ridge shape (convex shape) by etching to form an optical waveguide 10 consisting of a ridge portion 4, and a slab portion consisting of the dielectric thin film 3.

Next, a buffer layer 5 consisting of a SiO₂ film was formed by sputtering so as to cover the upper and side surfaces of the ridge portion 4.

Thereafter, a Ti film that becomes the second electrodes 8a, 8b, and 8c in contact with the upper surface of the slab portion consisting of the dielectric thin film 3 was formed by sputtering, and a Ti film that becomes the first electrodes 7a and 7b was formed on the buffer layer 5. Using the obtained Ti film as a seed layer, an Au film was formed on the Ti film by plating, and the second electrodes 8a, 8b, 8c and the first electrodes 7a, 7b were formed, each consisting of a laminated film of a Ti film and an Au film.

The above process resulted in the optical modulation components 200A with the substrates 1 with the dielectric thin film of each of Examples 1 to 15 and Comparative Examples 1 to 9.

### DC Drift Evaluation

For each of the optical modulation components 200A obtained in this manner, a DC drift evaluation was performed by the method described below.

The optical modulation component 200A was heated to 120° C., and a signal was input from the input sides 15a and 15b of the first electrodes 7a and 7b. At that time, a DC (direct current) voltage of 8 V was superimposed and applied from the first electrodes 7a and 7b to the second electrodes 8a, 8b and 8c in the in-plane direction of the dielectric thin film 3. Then, for one hour from the time when the DC (direct current) voltage was applied in the in-plane direction of the dielectric thin film 3, the modulated waveform of the output light output from the output optical waveguide 10c of the optical modulation component 200A to the output side 12 was observed by an oscilloscope.

As a result, those in which the DC drift calculated using the above formula (I) from the phase shift of the modulated waveform relative to the modulated waveform at the time of application of the DC voltage exceeded 50% before the application time of the DC voltage exceeded 1 hour were evaluated as failing, and those in which the DC drift did not exceed 50% before the application time of the DC voltage exceeded 1 hour were evaluated as passing. The results are shown in Tables 3 and 4.

FIG. 6 shows the results of observing, by an oscilloscope, the modulated waveform of the output light output from the output optical waveguide 10c of the optical modulation component 200A to the output side 12 for one hour from the time when a DC (direct current) voltage was applied in the in-plane direction of the dielectric thin film 3 for the optical modulation components 200A of Examples 5, 10, and Comparative Example 3.

FIG. 6 is a graph showing the relationship between time and DC drift in the modulated waveform of the output light output from the optical modulation components 200A of Example 5, Example 10, and Comparative Example 3.

As shown in FIG. 6, in the light modulation components 200A of Examples 5 and 10, the DC drift did not exceed 50% before the application time of the DC voltage exceeded one hour.

In contrast, in the light modulation component 200A of Comparative Example 3, the DC drift exceeded 50% before the application time of the DC (direct current) voltage exceeded one hour.

As shown in Table 3, in the substrates with dielectric thin films of Examples 1 to 15, the stress in the dielectric thin film was compressive stress, and there were no cracks in the dielectric thin film 3 or cracks caused by annealing.

In addition, in all of the optical modulation components of Examples 1 to 15, the amount of shift (DC drift) of the modulated waveform did not exceed 50% before the application time of the DC (direct current) voltage exceeded one hour, and the DC drift evaluation was passed.

In contrast, as shown in Table 4, in the optical modulation components using the substrates with dielectric thin films of Comparative Example 1 in which the maximum domain width of the first crystals 3a and the second crystals 3b of the dielectric thin film 3 is 68 nm, and Comparative Example 2 in which the maximum domain width of the first crystals 3a and the second crystals 3b of the dielectric thin film 3 is 70 nm, cracks in the dielectric thin film 3 and cracks caused by annealing were [present], and DC drift could not be evaluated.

In addition, as shown in Table 4 and FIG. 6, in the optical modulation component using the substrate with the dielectric thin film of Comparative Example 3 in which the maximum domain width of the first crystals 3a and the second crystals 3b of the dielectric thin film 3 is 75 nm, the shift amount (DC drift) of the modulation waveform exceeded 50% before the application time of the DC (direct current) voltage exceeded 1 hour, and the DC drift evaluation was failed. This is presumably because the maximum domain width of the first crystals 3a and the second crystals 3b of the dielectric thin film 3 is narrow, and therefore the number of twin boundaries crossed by the DC electric field is not sufficiently suppressed when a DC (direct current) voltage is applied in the in-plane direction from above the dielectric thin film 3.

In the substrate with dielectric thin film of Comparative Example 3, the stress value of the dielectric thin film 3 was −80 MPa or less, and there were no cracks in the dielectric thin film 3 or cracks caused by annealing.

Furthermore, as shown in Table 4, in the optical modulation components using the substrates with the dielectric thin film of Comparative Example 4 to Comparative Example 6 in which the maximum domain width of the first crystals 3a and the second crystals 3b of the dielectric thin film 3 exceeds 300 nm, the shift amount (DC drift) of the modulated waveform exceeded 50% before the application time of the DC (direct current) voltage exceeded 1 hour, and the DC drift evaluation was failed, as in Comparative Example 3. The cause of this is unknown, but it is possible that the number of crystal defects and/or dislocations present in the first crystals 3a and the second crystals 3b of the dielectric thin film 3 was large.

From these findings, it has been confirmed that when the maximum domain width of the first crystals 3a and the second crystals 3b of the dielectric thin film 3 is 80 nm to 300 nm, cracks are less likely to occur in the dielectric thin film 3, and furthermore, DC drift can be suppressed in an optical modulation component using this.

Furthermore, as shown in Table 4, in Comparative Example 7 using a substrate with a dielectric thin film 3 having a thickness of 0.3 μm, the amount of movement (DC drift) of the modulated waveform exceeded 50% before the application time of the DC (direct current) voltage exceeded one hour, and the DC drift evaluation was failed. This is presumably because the thickness of the dielectric thin film 3 was insufficient, and the influence of the DC electric field applied to the optical modulation component extended not only to the upper region 31 of the dielectric thin film 3 but also to the lower region 31.

In Comparative Example 8 and Comparative Example 9, which used a substrate with a dielectric thin film 3 having a thickness exceeding 2.0 μm, the amount of movement (DC drift) of the modulated waveform exceeded 50% before the application time of the DC (direct current) voltage exceeded one hour, and the DC drift evaluation was failed. This may be because the thickness of the dielectric thin film 3 was too thick, causing the shape of the optical waveguide 10 consisting of the ridge portion 4 of the optical modulation component formed by processing the dielectric thin film 3 into a ridge shape to become inappropriate.

From these, it was confirmed that by setting the thickness of the dielectric thin film 3 to 0.5 μm to 2 μm, DC drift can be suppressed in the optical modulation component using this.

### REFERENCE SYMBOL

1: Substrate with dielectric thin film
2: Single crystal substrate
2a: Main surface
3: Dielectric thin film
3a: First crystal
3b: Second crystal
4: Ridge portion
5: Buffer layer
7a, 7b: First electrode
8a, 8b, 8c: Second electrode
9: Termination resistor
10: Optical waveguide
10a: First optical waveguide
10b: Second optical waveguide
10c: Output optical waveguide
12: Output side
15a, 15b: Input side
31: Lower region
32: Upper region
100: Optical waveguide component
200A: Optical modulation component.

1. A substrate with a dielectric thin film comprising:
a single crystal substrate; and
a dielectric thin film formed in contact with a main surface of the single crystal substrate, wherein
the dielectric thin film has a thickness of 0.5 μm to 2 μm and is made of a lithium niobate film that is an epitaxial film with a c-axis orientation,
the dielectric thin film has a twin crystal structure of LiNbO₃ of a first crystal and a second crystal corresponding to a crystal in which the first crystal is rotated 180° around the c-axis,
the first crystal and the second crystal in an upper region of the dielectric thin film, excluding a lower region from the single crystal substrate to half of a thickness direction in the dielectric film, have maximum domain widths of 80 nm to 300 nm,
the maximum domain widths of the first crystal and the second crystal are median values of measured values obtained by setting a measurement region having a length of 4 μm in a cross section at an arbitrary location on an interface between the dielectric thin film and the single crystal substrate and measuring crystal domain widths of 10 or more arbitrary first and second crystals present within the measurement region, each of the crystal domain widths being a crystal width in a direction perpendicular to a growth direction of each crystal and maximum dimension within the thickness direction.

2. The substrate with a dielectric thin film according to claim 1, wherein a part or all of the first crystal and the second crystal in the dielectric thin film have non-uniform domain widths within the thickness direction.

3. The substrate with a dielectric thin film according to claim 1, wherein the single crystal substrate is a sapphire single crystal substrate, the main surface of which is a c-plane.

4. The substrate with a dielectric thin film according to claim 1, wherein
a ratio of a first diffraction intensity to a second diffraction intensity is 0.5 or more and 2.0 or less in the twin crystal structure, the first diffraction intensity and second diffraction intensity being diffraction intensities of the first crystal and the second crystal, respectively, in a pole figure measurement by an X-ray diffraction method.

5. An optical waveguide component comprising the substrate with a dielectric thin film according to claim 1.

6. The optical waveguide component according to claim 5 comprising an optical waveguide made of the dielectric thin film.

7. An optical modulation component comprising the substrate with a dielectric thin film according to claim 1.

8. The optical modulation component according to claim 7, further comprising:
an optical wave guide made of the dielectric thin film; and
a first electrode and a second electrode, both of which are configure to apply voltage in an in-plane direction from above the dielectric thin film, the voltage changing a refractive index of the optical waveguide.
